(19) United States
(12) Patent Application Publication
(10) Pub. No.: US 2003/0222348 A1
(43) Pub. Date: Dec. 4, 2003

(54) Semiconductor device

(75) Inventor: Masakazu Okada, Tokyo (JP)

Correspondence Address: OBLON, SPIVAK, MCCELLAND, MAIER & NEUSTADT, 1755 JEFFERSON DAVIS HIGHWAY, FOURTH FLOOR, ARLINGTON, VA, 22202, US

(73) Assignee: MITSUBISHI DENKI KABUSHIKI KAISHA, TOKYO (JP)

(21) Appl. No.: 10/279,922

(22) Filed: Oct. 25, 2002

(30) Foreign Application Priority Data
May 29, 2002 (JP) 2002-155399

(51) Int. Cl. H01L 23/48

(52) U.S. Cl. 257/758

(57) ABSTRACT

A semiconductor device (100) includes a pad area (5) in which a plurality of protrusions (52) formed of a nitride layer (3) and an interlayer oxide film (4) are formed on a Cu layer (21) of a Cu wiring layer. An aluminum electrode (6) is formed on the protrusions (52) and the Cu layer (21). The aluminum electrode (6) has an alumina layer (64) of an oxide film formed in an upper face thereof, and includes irregularities extending along the protrusions (52). The foregoing structure of the pad area (5) reduces a contact area between a probe and the device in a probe test. Hence, it is possible to surely peel of the oxide film in a surface of the pad area (5) without applying an excessive pressure to the probe, to ensure sufficient pin contact.

### BACKGROUND OF THE INVENTION

1. Field of the Invention

The present invention relates to a semiconductor device including a pad area.

2. Description of the Background Art

FIGS. 20 through 24 are sectional views schematically illustrating structures at respective steps in order of occurrence in a method of manufacturing a conventional semiconductor device.

First, a semiconductor element area ST is formed on a semiconductor substrate 1, and subsequently, a Cu wiring layer 2 is formed (FIG. 20). The Cu wiring layer 2 is composed of a Cu layer 21 and an interlayer oxide film 22.

Secondly, a nitride film 3 is deposited on the Cu wiring layer 2, and subsequently, an interlayer oxide film 4 is deposited on the nitride film 3. Then, a resist layer is formed on the interlayer oxide film 4, to be patterned by a photolithography process. Thereafter, a selective etching process is performed on the interlayer oxide film 4 using a remainder of the patterned resist layer as a mask, and the remainder of the patterned resist layer is removed using an O₂ plasma. Further, a portion of the nitride film 3 is etched using the etched interlayer oxide film 4 as a mask, to form an opening 51 for a pad area 5 (FIG. 21). As a result of this etching process, the nitride film 3 and the interlayer oxide film 4 are removed from an entire surface of the opening 51.

Next, a barrier metal layer 61, an aluminum layer 62 and a titanium nitride (TIN) layer 63 are sequentially formed on the interlayer oxide film 4 and the Cu wiring layer 2 by a sputtering process, and subsequently a resist layer is formed on the titanium nitride layer 63, to be patterned by a photolithography process. Then, a selective etching process is performed on a layered structure formed of the barrier metal layer 61, the aluminum layer 62 and the titanium nitride layer 63, using a remainder of the patterned resist layer as a mask, and the remainder of the resist layer is removed using an O₂ plasma. As a result, an aluminum electrode (hereinafter referred to as an “AL electrode”) 6 in the pad area 5 is formed (FIG. 22).

Then, a nitride film 7 is deposited on the resultant structure by a plasma enhanced CVD process, and a resist layer is formed on the nitride film 7, to be patterned by a photolithography process. Subsequently, a selective etching process is performed on the nitride film 7 using a remainder of the patterned resist layer as a mask, and the remainder of the patterned resist layer is removed using an O₂ plasma. As a result, a portion of the nitride film 7 which is located above the AL electrode 6 in the pad area 5 is opened (FIG. 23). By this etching process, a portion of the titanium nitride layer 63 of the AL electrode 6, which portion is located under the opened portion of the nitride film 7, is etched along with the nitride film 7. Further, simultaneously therewith, an upper surface of a portion of the aluminum layer 62, which portion is located under the opened portion of the nitride film 7, is oxidized by the O₂ plasma, to become alumina, having undergone quality change. Thus, an alumina layer 64 having an insulating property is generated.

Lastly, a photosensitive polyimide layer 8 is coated on the resultant structure. Then, a photolithography process and development are performed on the photosensitive polyimide layer 8, so that a portion of the polyimide layer 8 which is located above the AL electrode 6 in the pad area 5 is removed to form an opening 81 (FIG. 24). As a result, a semiconductor device including the opening 81 is manufactured.

While the semiconductor device as manufactured through the foregoing processes is ready for an assembling process, it is general that a test is performed on the semiconductor device which is still in a state of wafer, prior to the assembling process. A probe 59 is brought into contact with the semiconductor device in the test which will be hereinafter referred to as a “probe test” (FIG. 25). In the probe test, it is required to peel off the alumina layer 64 by applying a pressure on the pad area 5 via the probe 59, to place the probe 59 and the aluminum layer 62 into contact with each other.

However, the conventional semiconductor device as described above has an disadvantage in performing a probe test thereon. Specifically, if an excessive pressure is applied to the probe 59 for the purpose of surely peeling off the alumina layer 64, a crack 22c occurs in a portion of the interlayer oxide film 22 which is located under the AL electrode 6 as illustrated in FIG. 25. The occurrence of the crack 22c causes a problem of forming a short circuit between a Cu layer 21a and a Cu layer 21b which are arranged so as to form a multi-layer structure.

To avoid the foregoing problem, reducing a pressure to be applied for placing the probe 59 into contact with the device is effective. However, this would make it impossible to peel off the alumina layer 64 (which is generally formed of an oxide film), which causes another problem of generating an open-circuit failure in making contact with the probe for the test (such contact will hereinafter be referred to as “pin contact”).

### SUMMARY OF THE INVENTION

It is an object of the present invention to provide a semiconductor device which allows an oxide film in a surface of a pad area to be surely peeled off without application of an excessive pressure to a probe for a probe test, to ensure sufficient pin contact.

A semiconductor device according to the present invention includes a semiconductor substrate, a wiring layer, a protrusion layer and a conductive layer. The semiconductor substrate includes a semiconductor element area. The wiring layer is formed on a main surface of the semiconductor substrate. The protrusion layer is selectively formed on the wiring layer in a predetermined pad area and includes at least one protrusion. The conductive layer covers an uneven surface made of respective exposed surfaces of the protrusion layer and the wiring layer in the predetermined pad area, to include irregularities extending along the uneven surface.

Because of the presence of the protrusion layer including at least one protrusion in the pad area, unevenness is caused in the conductive layer on the wiring layer, so that irregularities are generated in an oxide film (such as an alumina layer) in a surface of the conductive layer. This makes it possible to surely peel off the oxide film in the surface of the pad area without applying an excessive pressure to a probe in a probe test, to ensure sufficient pin contact.

Preferably, the protrusion layer is thinner than the conductive layer.

As a result, occurrence of overhang in the conductive layer can be prevented.

Preferably, the protrusion layer includes a plurality of protrusions which are arranged radially from around a center of the predetermined pad area.

As a result, resistance of the pad area can be reduced.

Preferably, the protrusion layer includes a plurality of protrusions each of which is conical in section taken along a plane perpendicular to the wiring layer.

As a result, the oxide film can be peeled off more easily.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 5 are sectional views schematically illustrating structures at respective stages in order of occurrence in a method of manufacturing a semiconductor device according to a first preferred embodiment of the present invention.

FIG. 6 illustrates a layout of an opening of a pad area.

FIGS. 7 through 10 are sectional views schematically illustrating structures at respective stages in order of occurrence in a method of manufacturing a semiconductor device according to a second preferred embodiment of the present invention.

FIGS. 11A, 11B and 11C are enlarged views for illustrating a procedure for forming a conical protrusion by HDP (High Density Plasma).

FIGS. 12 through 16 are sectional views schematically illustrating structures at respective stages in order of occurrence in a method of manufacturing a semiconductor device according to a third preferred embodiment of the present invention.

FIG. 17 illustrates an exemplary layout of an opening of a pad area according to modifications of the present invention.

FIGS. 18A, 18B and 18C illustrate reduction of resistance achieved by radially arranging protrusions.

FIGS. 19A and 19B illustrate another exemplary layouts of an opening of a pad area according to the modifications of the present invention.

FIGS. 20 through 24 are sectional views schematically illustrating structures at respective stages in order of occurrence in a method of manufacturing a conventional semiconductor device.

FIGS. 25 and 26 are sectional views for illustrating problems associated with the conventional semiconductor device.

### DESCRIPTION OF THE PREFERRED EMBODIMENTS

Preferred Embodiments

First Preferred Embodiment

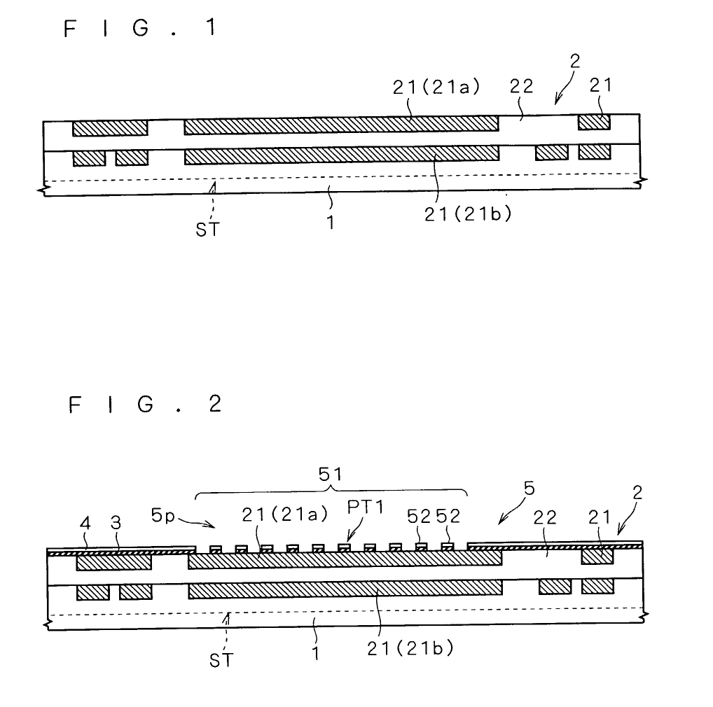

FIGS. 1 through 5 are sectional views schematically illustrating structures at respective steps in order of occurrence in a method of manufacturing a semiconductor device 100 according to a first preferred embodiment of the present invention.

First, a semiconductor element area ST is formed in a main surface of a semiconductor substrate 1 which is in a state of silicon wafer, and subsequently, a Cu wiring layer 2 is formed on the main surface of the semiconductor substrate 1 (FIG. 1). The Cu wiring layer 2 includes a Cu layer 21 (composed of an upper Cu layer 21a and a lower Cu layer 21b) and an interlayer oxide film 22. The Cu wiring layer 2 is electrically connected with the semiconductor element area ST.

Secondly, a nitride film 3 is deposited on the Cu wiring layer 2, and subsequently, an interlayer oxide film 4 is deposited on the nitride film 3. Then, a resist layer is formed on the interlayer oxide film 4, to be patterned by a photolithography process. Thereafter, a selective etching process is performed on the interlayer oxide film 4 using a remainder of the patterned resist layer as a mask, and the remainder of the patterned resist layer is removed using an O₂ plasma.

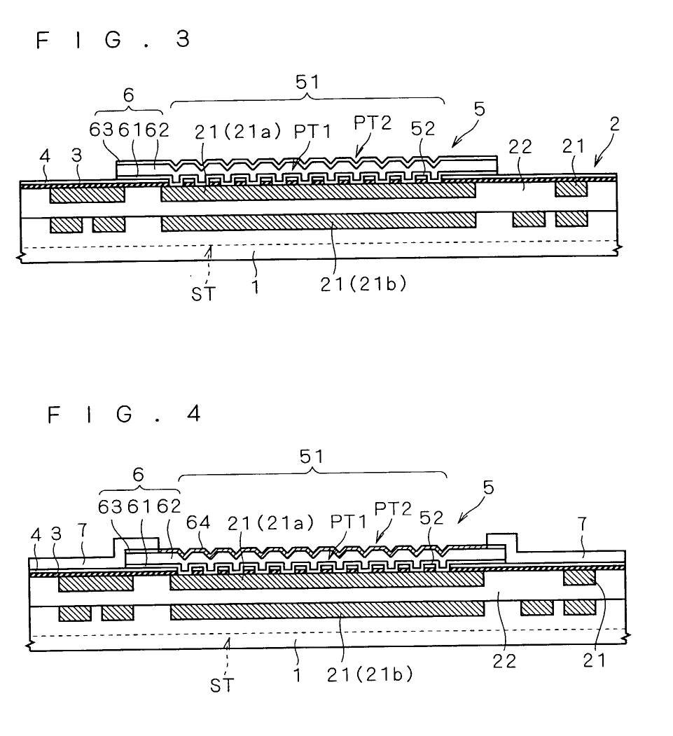

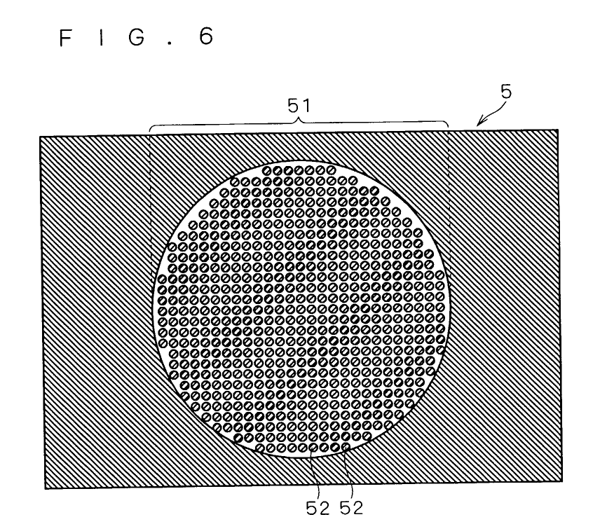

Further, another selective etching process is performed on the nitride film 3 using the patterned interlayer oxide film 4 as a mask, to form an opening 51 for a pad area 5 in the nitride film 3 (FIG. 2). In particular, portions of insulating films (i.e., the nitride film 3 and the interlayer oxide film 4) formed on the Cu wiring layer 2 in the pad area 5 are selectively removed, so that a first protrusion layer PT1 formed of a plurality of fine protrusions 52 is provided. As illustrated in FIG. 6, the opening 51 is substantially circular on a plane parallel to the main surface of the semiconductor substrate 1 (and thus parallel to a main surface of the Cu wiring layer 2), and includes a layout in which the plurality of protrusions 52 each having a substantially circular section taken along the plane are arranged so as to form a grid. Since each of the plurality of protrusions 52 has a substantially circular section taken along a line parallel to the Cu wiring layer 2, it is possible to easily peel off the alumina layer 64, which will be described in detail below.

Preferably, a film thickness of each of the protrusions 52 which are selectively provided to form a protrusion array 5p on the Cu wiring layer 2, in other words, a film thickness of each of numerous multilevel films (layered islands composed of the nitride film 3 and the interlayer oxide film 4) selectively provided in the pad area 5, is controlled so as to be lower than a film thickness of an aluminum electrode 6 in the pad area 5 (see FIG. 3) which is to be formed on the protrusions 52 in a later step. This allows for prevention of overhang at a portion of the aluminum electrode 6 in the pad area 5, which portion is located on each of the protrusions 52. It is desired to prevent such overhang because, in forming a bump in the semiconductor device 100 as manufactured (see FIG. 5), a film to be sputtered is not attached to a side including an overhang so that a void or the like remains, which is likely to cause a problem such as corrosion.

Next, a barrier metal layer 61, an aluminum layer 62 and a titanium nitride layer 63 are sequentially formed on a region including respective exposed surfaces of the Cu wiring layer 2 and the array of the protrusions 52, by a sputtering process, to obtain a layered structure formed of those three layers. Thereafter, a resist layer is formed on the titanium nitride layer 63, to be patterned by a photolithography process. Then, a selective etching process is performed on the layered structure (the barrier metal layer 61, the aluminum layer 62 and the titanium nitride layer 63) using a remainder of the patterned resist layer as a mask, and the remainder of the resist layer is removed using an O₂ plasma. As a result, the aluminum electrode (AL electrode) 6 in the pad area 5 is formed (FIG. 3). At that time, it is preferable to employ a sputtering process for forming the barrier metal layer 61, the aluminum layer 62 and the titanium nitride layer 63, in order to allow the AL electrode 6 to have a substantially uniform thickness. The AL electrode 6 as formed through the foregoing processes covers an uneven surface made of the respective exposed surfaces of the first protrusion layer PT1, i.e., the protrusion array 5p, and the Cu wiring layer 2, to include irregularities PT2 extending along the uneven surface, within the pad area 5.

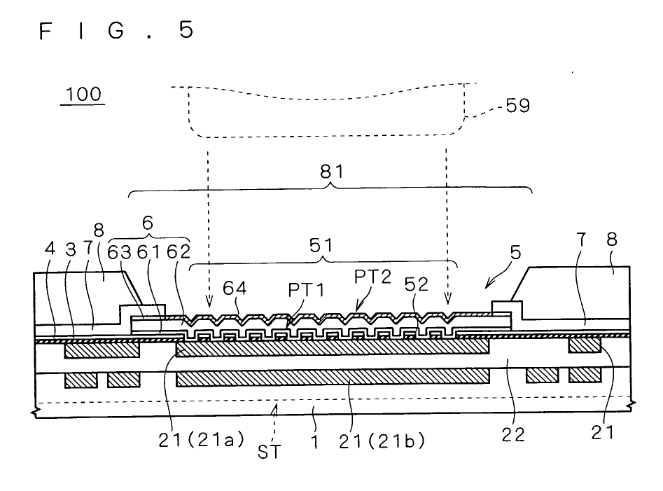

Thereafter, a nitride film 7 is deposited on the resultant structure by a plasma enhanced CVD process, and a resist layer is formed on the nitride film 7, to be patterned by a photolithography process. Then, a selective etching process is performed on the nitride film 7 using a remainder of the patterned resist layer as a mask, and the remainder of the resist layer is removed using an O₂ plasma. As a result, a portion of the nitride film 7 which is located above the AL electrode 6 in the pad area 5 is opened (FIG. 4). Additionally, it is preferable to perform this etching process in an isotropic manner, in order to prevent formation of a sidewall.

By the etching process on the nitride film 7, a portion of the titanium nitride layer 63 of the AL electrode 6, which portion is located under the opened portion of the nitride film 7, is etched along with the nitride film 7. Further, simultaneously therewith, an upper surface of a portion of the aluminum layer 62, which portion is located under the opened portion of the nitride film 7, is oxidized by the O₂ plasma, to become alumina, having undergone quality change. Thus, an alumina layer 64 having an insulating property is generated. Accordingly, the irregularities PT2 form a pattern of an array composed of numerous fine islands each including a layered structure formed of the barrier metal layer 61, the aluminum layer 62 and the alumina layer 64.

Lastly, a photosensitive polyimide layer 8 is coated on the resultant structure. Then, a photolithography process and development are performed on the photosensitive polyimide layer 8, so that a portion of the polyimide layer 8 which is located above the AL electrode 6 in the pad area 5 is removed to form an opening 81 (FIG. 5). As a result, the semiconductor device 100 including the opening 81 is manufactured.

The semiconductor device 100 manufactured by the method described above includes unevenness in a surface of the pad area 5. This results in a reduced contact area between a tip of the probe 59 and the device when a pressure is applied to the tip of the probe 59 while placing the tip of the probe 59 into contact with the pad area 5 of the opening 51, for a probe test. Because of the reduced contact area, the alumina layer 64 can be peeled off with a lower pressure to be applied to the probe 59 than that in the conventional semiconductor device in which the pad area has a flat surface. As a result, it is possible to surely peel off the alumina layer 64 in the surface of the pad area without applying an excessive pressure to the probe 59, thereby to ensure sufficient pin contact. Therefore, a probe test in which a voltage for a test is applied to the probe 59, or an output of the semiconductor device 100 is taken out from the probe 59, can be performed with accuracy.

Second Preferred Embodiment

FIGS. 7 through 10 are sectional views schematically illustrating structures at respective steps in order of occurrence in a method of manufacturing a semiconductor device 200 according to a second preferred embodiment of the present invention.

First, the semiconductor element area ST is formed in the main surface of the semiconductor substrate 1 which is in a state of wafer, and subsequently the Cu wiring layer 2 is formed on the main surface of the semiconductor substrate 1, in the same manner as in the first preferred embodiment, to obtain the structure illustrated in FIG. 1. Next, the nitride film 3 and the interlayer oxide film 4 are sequentially deposited on the resultant structure, which are followed by a photolithography process to pattern a resist layer as formed, an etching process on the nitride film 3 and the interlayer oxide film 4, and removal of the resist layer using an O2 plasma, also in the same manner as in the first preferred embodiment, to obtain a structure illustrated in FIGS. 2 and 6 in which the protrusion array 5p is formed in the pad area 5.

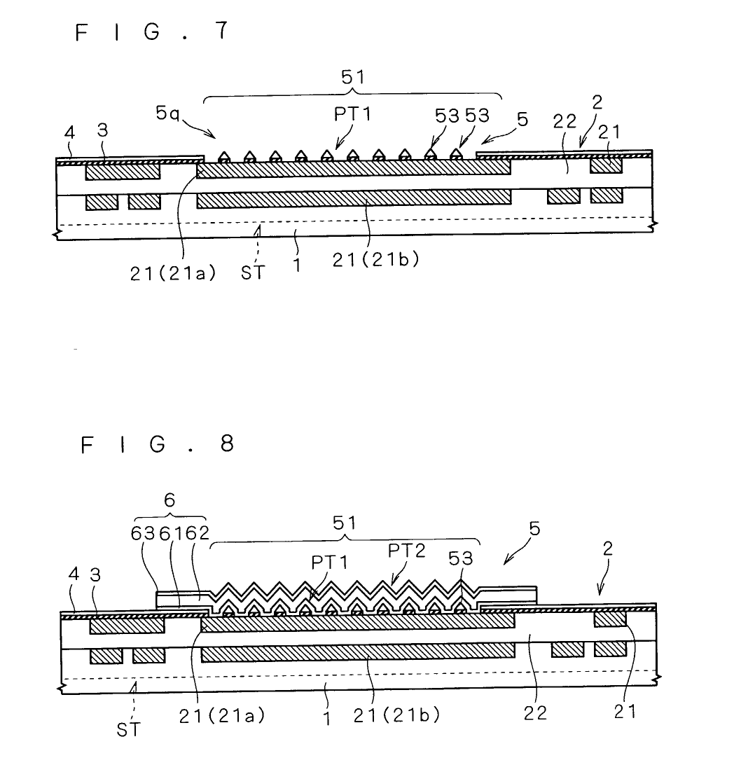

Then, the interlayer oxide film 4 is further deposited by a high density plasma enhanced CVD process (which will be hereinafter abbreviated as a “HDP”), and subsequently, the deposited interlayer oxide film 4 is etched back, to form protrusions 53. At that time, the interlayer oxide film 4 is etched back until each of the protrusions 53 being formed in the pad area 5 has a height substantially equal to the film thickness of the AL electrode 6 to be formed (see FIG. 8). As a result, a protrusion array 5q formed of the numerous protrusions 53 each having a conical upper portion as illustrated in FIG. 7. The protrusions 53 as noted above can serve to prevent occurrence of an overhang in the AL electrode 6 which is to be formed on the protrusions 53 in a later step. A procedure for forming the conical protrusions 53 by HDP will be described in detail below.

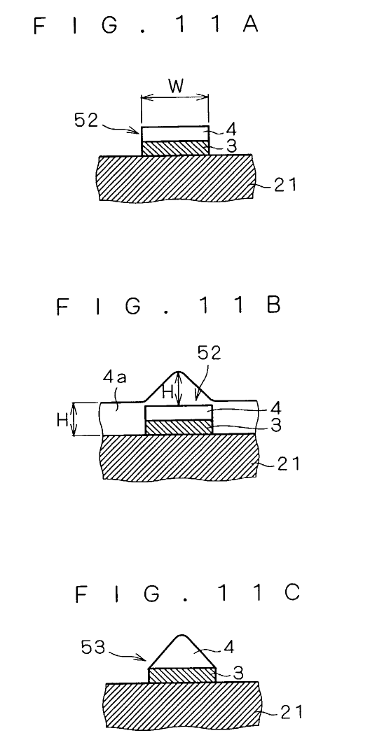

FIGS. 11A, 11B and 11C are enlarged views for illustrating the procedure for forming the conical protrusions 53 by HDP.

First, an oxide film 4a is deposited on the protrusion 52 (see FIG. 2) on the Cu wiring layer 2 which is illustrated in FIG. 11A, by HDP (FIG. 11B). At that time, as a result of employment of HDP which provides a great difference in film thickness of a film to be formed between a situation where a film is formed on a flat surface with a broad plane and a situation where a film is formed on an uneven surface with small planes, the oxide film 4a having a central portion uplifted is deposited on the protrusion 52. Assuming that a direction in which a plane parallel to the Cu wiring layer 2 extends is a horizontal direction, the oxide film 4a is deposited until it has a height H which is about a half of a width W in the horizontal direction of the protrusion 52. Accordingly, when a section of the protrusion 52 taken along the horizontal direction is substantially circular, it is preferable that the height H is substantially equal to a half of a diameter, i.e., a radius, of the protrusion 52 in section taken along the horizontal direction. Then, the interlayer oxide film 4 as formed is etched back, so that the protrusion 53 having an upper portion sharpened with an acute angle, in other words, having a central portion thereof uplifted, is formed as illustrated in FIG. 11C. Each of the protrusions 53 formed through the foregoing processes is conical in section perpendicular to the Cu wiring layer 2, while it is substantially circular in section parallel to the Cu wiring layer, i.e., parallel to the horizontal direction. This makes it possible to easily peel of the alumina layer 64.

Next, the barrier metal layer 61, the aluminum layer 62 and the titanium nitride layer 63 are sequentially formed on a region including respective exposed surfaces of the Cu wiring layer 2 and the protrusions 53, by a sputtering process. Subsequently, a resist layer is formed on the titanium nitride layer 63, to be patterned by a photolithography process. Then, a selective etching process is performed on a layered structure of the barrier metal layer 61, the aluminum layer 62 and the titanium nitride layer 63 using a remainder of the patterned resist layer as a mask, and the remainder of the resist layer is removed using an O₂ plasma. As a result, the aluminum electrode (AL electrode) 6 in the pad area 5 is formed (FIG. 8). The AL electrode 6 as formed through the foregoing processes covers an uneven surface made of respective exposed surfaces of the first protrusion layer PT1, i.e., the protrusion array 5q, and the Cu wiring layer 2, to include the irregularities PT2 extending along the uneven surface, within the pad area 5.

Thereafter, the nitride film 7 is deposited on the resultant structure by a plasma enhanced CVD process, and a resist layer is formed on the nitride film 7, to be patterned by a photolithography process. Then, a selective etching process is performed on the nitride film 7 using a remainder of the patterned resist layer as a mask, and the remainder of the resist layer is removed using an O₂ plasma. As a result, a portion of the nitride film 7 which is located above the AL electrode 6 in the pad area 5 is opened (FIG. 9). Additionally, it is preferable to perform this etching process in an isotropic manner, in order to prevent formation of a sidewall.

By the etching process on the nitride film 7, a portion of the titanium nitride layer 63 of the AL electrode 6, which portion is located under the opened portion of the nitride film 7, is etched along with the nitride film 7. Further, simultaneously therewith, an upper surface of a portion of the aluminum layer 62, which portion is located under the opened portion of the nitride film 7, is oxidized by the O₂ plasma, to become alumina, having undergone quality change. Thus, the alumina layer 64 having an insulating property is generated. Accordingly, the irregularities PT2 form a pattern of an array composed of numerous fine islands each including a layered structure of the barrier metal layer 61, the aluminum layer 62 and the alumina layer 64.

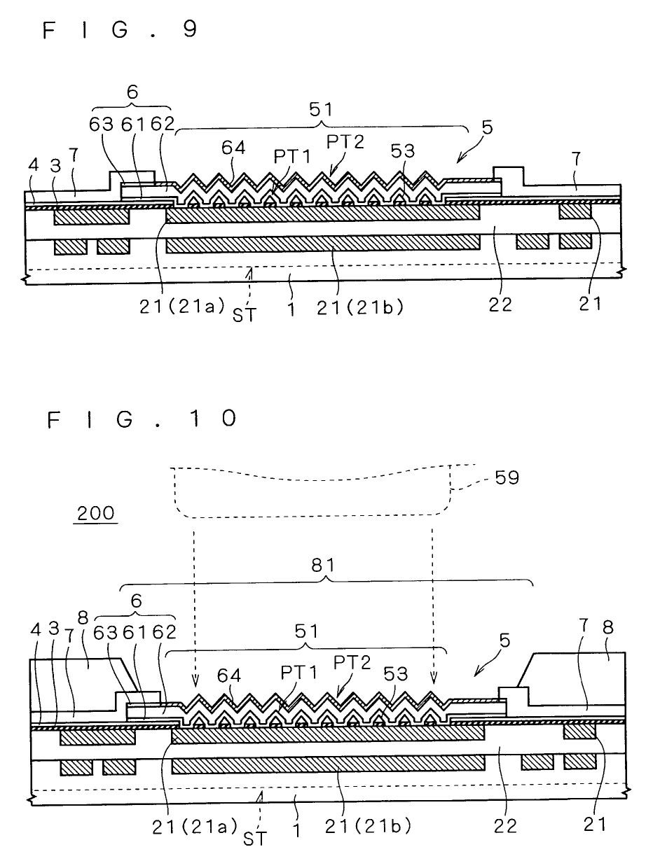

Lastly, the photosensitive polyimide layer 8 is coated on the resultant structure. Then, a photolithography process and development are performed on the photosensitive polyimide layer 8, so that a portion of the polyimide layer 8 which is located above the AL electrode 6 in the pad area 5 is removed to form the opening 81 (FIG. 10). As a result, the semiconductor device 200 including the opening 81 is manufactured.

The semiconductor device 200 manufactured by the method described above includes unevenness in a surface of the pad area 5. As with the first preferred embodiment, it is possible to surely peel off the alumina layer 64 in the surface of the pad area without applying an excessive pressure to the probe 59, thereby to ensure sufficient pin contact, in a probe test. Furthermore, the semiconductor device 200 according to the second preferred embodiment includes the protrusions 53 each having a conical upper portion, so that the irregularities in the surface of the AL electrode 6 are sharp. This makes it possible to peel off the alumina layer 64 more easily. Therefore, a probe test in which a voltage for a test is applied to the probe 59, or an output of the semiconductor device 200 is taken out from the probe 59, can be performed with accuracy.

Third Preferred Embodiment

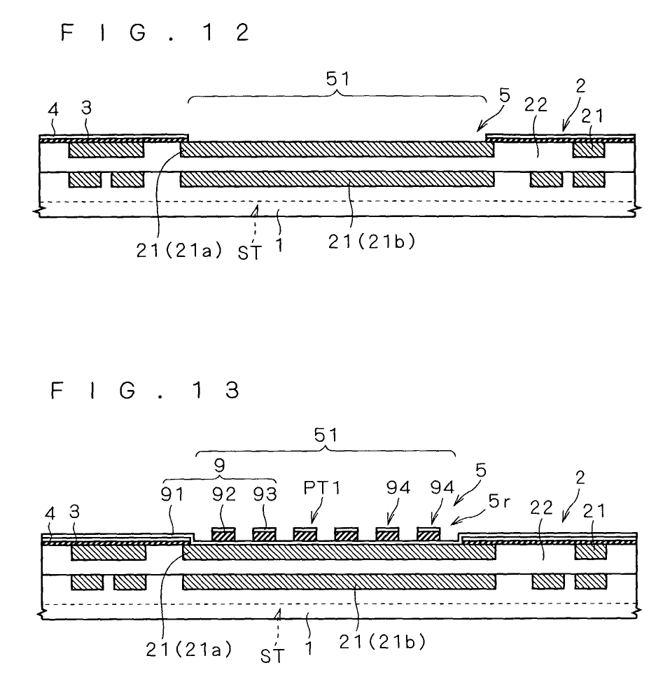

FIGS. 12 through 16 are sectional views schematically illustrating structures at respective steps in order of occurrence in a method of manufacturing a semiconductor device 300 according to a third preferred embodiment of the present invention.

First, the semiconductor element area ST is formed in the main surface of the semiconductor substrate 1 which is in a state of wafer, and subsequently the Cu wiring layer 2 is formed on the main surface of the semiconductor substrate 1, in the same manner as in the first preferred embodiment, to obtain the structure illustrated in FIG. 1. Next, the nitride film 3 and the interlayer oxide film 4 are sequentially deposited on the resultant structure also in the same manner as in the first preferred embodiment. However, unlike the first preferred embodiment, it would make no material difference in technical effects whether or not the total film thickness of the nitride film 3 and the interlayer oxide film 4 may be specifically chosen. Thereafter, a photolithography process to pattern a resist layer as formed, an etching process on the nitride film 3 and the interlayer oxide film 4 and removal of the resist layer using an O₂ plasma are performed, to form the opening 51 for the pad area 5 (FIG. 12). At that time, the nitride film 3 and the interlayer oxide film 4 are removed from an entire surface of the opening 51, unlike the first and second preferred embodiments.

Next, a barrier metal layer 91, an aluminum layer 92 and a titanium nitride layer 93 are sequentially formed on the Cu wiring layer 2 by a sputtering process. Subsequently, a resist layer is formed on the titanium nitride layer 93, to be patterned by a photolithography process. Then, a selective etching process is performed on a layered structure of the barrier metal layer 91, the aluminum layer 92 and the titanium nitride layer 93 using a remainder of the patterned resist layer as a mask, and the remainder of the patterned resist layer is removed using an O₂ plasma. As a result, a film of a first layered structure 9 is formed in the pad area 5 (FIG. 13). The opening 51 of the pad area 5 includes a layout in which a plurality of fine protrusions 94 each having a horizontal surface shaped like a disk are arranged so as to form a grid as illustrated in FIG. 6. Since each of the plurality of protrusions 94 which form a protrusion array 5r, i.e., the protrusion layer PT1, is substantially circular in horizontal section taken along a plane parallel to the Cu wiring layer 2, it is possible to easily peel off the alumina layer 64.

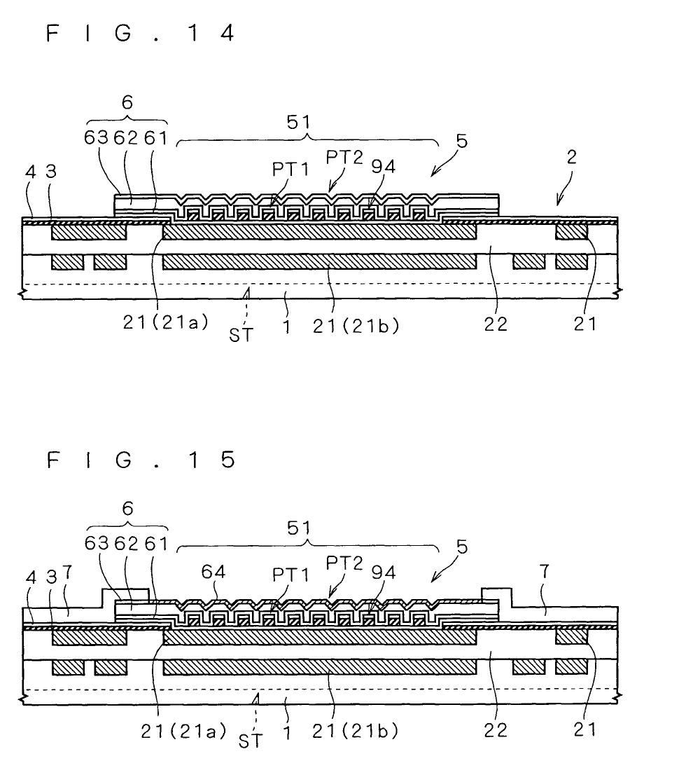

Further, a film thickness of each of the protrusions 94 which are selectively provided to form the protrusion array 5r on the Cu wiring layer 2, in other words, a film thickness of the first layered structure 9 formed of the barrier metal layer 91, the aluminum layer 92 and the titanium nitride layer 93 is controlled so as to be lower than a film thickness of the AL electrode 6 in the pad area 5 which is to be formed on the protrusions 94 in a later step (see FIG. 14). This allows for prevention of overhang at a portion of the AL electrode 6 in the pad area 5, which portion is located on each of the protrusions 94.

Next, the barrier metal layer 61, the aluminum layer 62 and the titanium nitride layer 63 are sequentially formed on a region including respective exposed surfaces of the Cu wiring layer 2 and the protrusions 94, by a sputtering process. Thereafter, a resist layer is formed on the titanium nitride layer 63, to be patterned by a photolithography process. Then, a selective etching process is performed on a second layered structure formed of the barrier metal layer 61, the aluminum layer 62 and the titanium nitride layer 63 using a remainder of the patterned resist layer as a mask, and the remainder of the patterned resist layer is removed using an O₂ plasma. As a result, the AL electrode 6 in the pad area 5 is formed (FIG. 14). The AL electrode 6 formed through the foregoing processes covers an uneven surface made of the respective exposed surfaces of the protrusion array 5r, i.e., the protrusion layer PT1, and the Cu wiring layer 2, to include the irregularities PT2 extending along the uneven surface.

Thereafter, the nitride film 7 is deposited on the resultant structure by a plasma enhanced CVD process, and a resist layer is formed on the nitride film 7, to be patterned by a photolithography process. Then, a selective etching process is performed on the nitride film 7 using a remainder of the patterned resist layer as a mask, and the remainder of the patterned resist layer is removed using an O₂ plasma. As a result, a portion of the nitride film 7 which is located above the AL electrode 6 is opened (FIG. 15). Additionally, it is preferable to perform this etching process in an isotropic manner, in order to prevent formation of a sidewall.

By the etching process on the nitride film 7, a portion of the titanium nitride layer 63 of the AL electrode 6, which portion is located under the opened portion of the nitride film 7, is etched along with the nitride film 7. Further, simultaneously therewith, a surface of a portion of the aluminum layer 62 of the AL electrode 6, which portion is located under the opened portion of the nitride film 7, is oxidized by the O₂ plasma, to become alumina, having undergone quality change. Thus, the alumina layer 64 having an insulating property is generated.

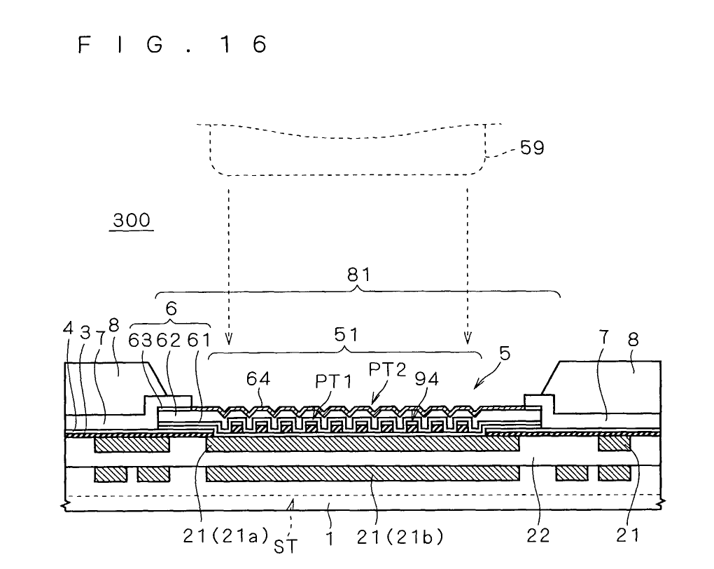

Lastly, the photosensitive polyimide layer 8 is coated on the resultant structure. Then, a photolithography process and development are performed on the photosensitive polyimide layer 8, so that a portion of the polyimide layer 8 which is located above the AL electrode 6 is removed to form the opening 81 (FIG. 16). As a result, the semiconductor device 300 including the opening 81 is manufactured.

The semiconductor device 300 manufactured by the method described above includes unevenness in a surface of the pad area 5. As with the first and second preferred embodiments, it is possible to surely peel off the alumina layer 64 in the surface of the pad area without applying an excessive pressure to the probe 59, thereby to ensure sufficient pin contact. Therefore, a probe test in which a voltage for a test is applied, or an output of the semiconductor device 300 is taken out from the probe 59, can be performed with accuracy.

Furthermore, unlike the first and second preferred embodiments in which the protrusion layer PT1 in the pad area 5 is made of an insulating film (nitride/oxide film), the protrusion layer PT1 in the pad are 5 is made of metal, so that metal-to-metal contact is made between the protrusion layer PT1 and the Cu layer 21 in the third preferred embodiment. This produces a further advantage of preventing an electromigration failure or the like from being caused due to scratching the lower Cu layer 21 when the probe 59 is brought into contact with the device. However, generally, the protrusion layer PT1 may be made of either an insulative material or a conductive material.

Modifications

In the first preferred embodiment above described, it is not essential to arrange the plurality of protrusions 52 so as to form a grid as illustrated in FIG. 6. Alternatively, the plurality of protrusions 52 may be arranged radially from around a center of the pad area 5 as illustrated in FIG. 17. Such radial arrangement of the protrusions 52 allows for reduction of resistance as compared with “grid arrangement” described above in the first preferred embodiment.

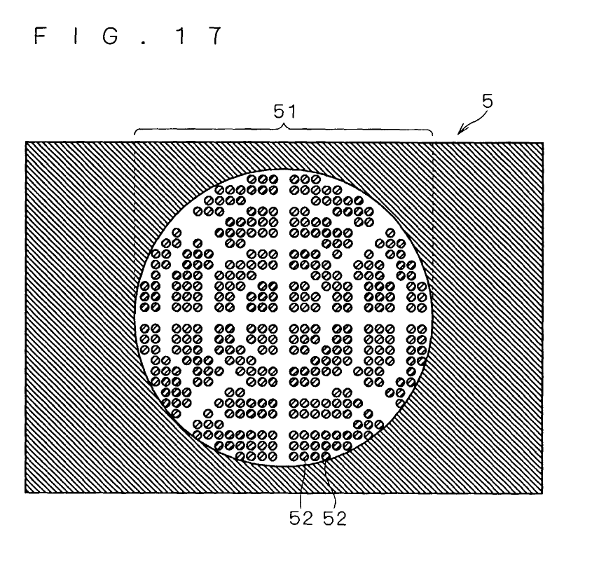

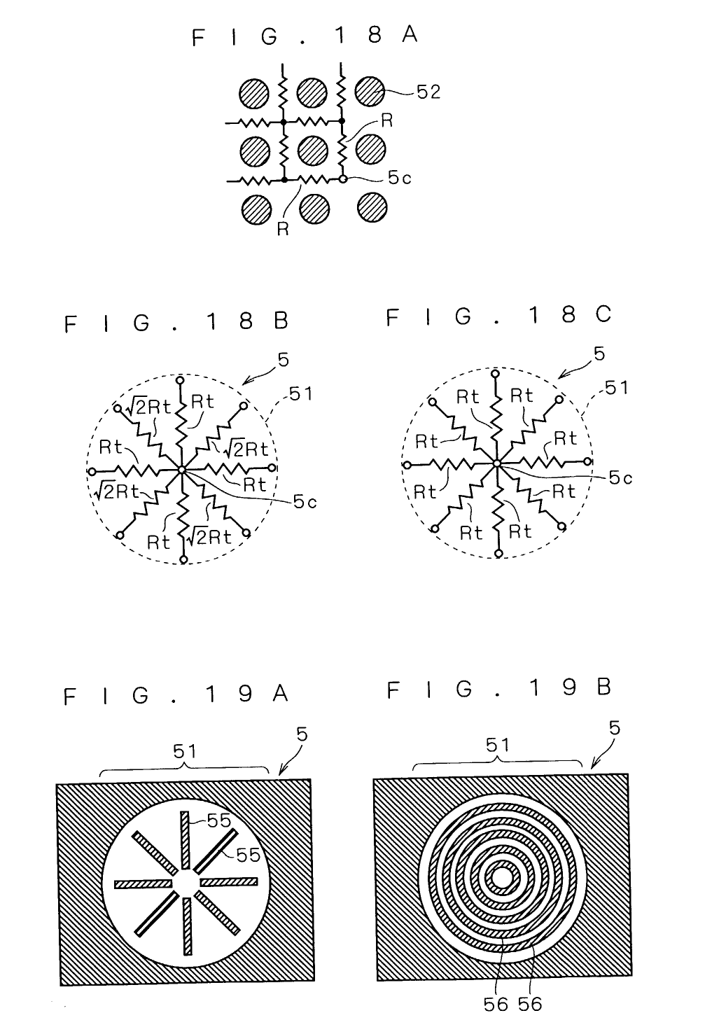

FIGS. 18A through 18C illustrate reduction of resistance achieved by the radial arrangement of the protrusions 52. FIG. 18A shows the protrusions 52 present in the vicinity of a center 5c of the opening 51 illustrated in FIG. 6.

In the semiconductor device 100, the protrusions 52 which are insulative are interposed between the AL electrode 6 and the Cu wiring layer 2. In a case where the protrusions 52 are arranged so as to form a grid, resistances R will be probably provided as shown in FIG. 18A. Accordingly, an equivalent circuit of the pad area 5 is represented as shown in FIG. 18B. In particular, assuming that a value of a resistance caused in a direction parallel to a line of the grid formed by the protrusions is Rt, a value of a resistance caused in a slanting direction relative to the line of the grid is (\sqrt{2})Rt. On the other hand, in a case where the protrusions 52 are radially arranged, an equivalent circuit of the pad area 5 is represented as shown in FIG. 18C. In the case of radial arrangement, resistances, each of which is caused in a direction from the center 5c toward a periphery of the pad area 5, have the same resistance value Rt. As such, to radially arrange the protrusions 52 will reduce a resistance as a whole as compared with the “grid arrangement”.

The same modifications as noted above are applicable to the second and third preferred embodiments. In short, by radially arranging the protrusions 52 or 53, reduction of resistance can be achieved.

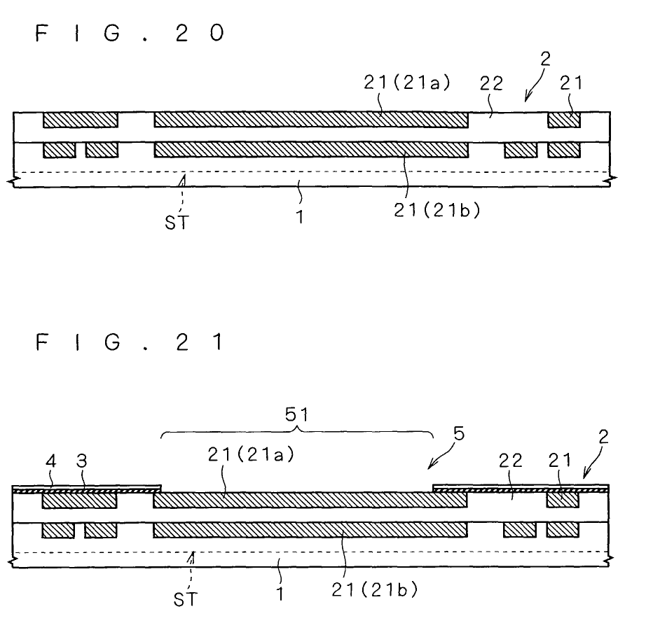

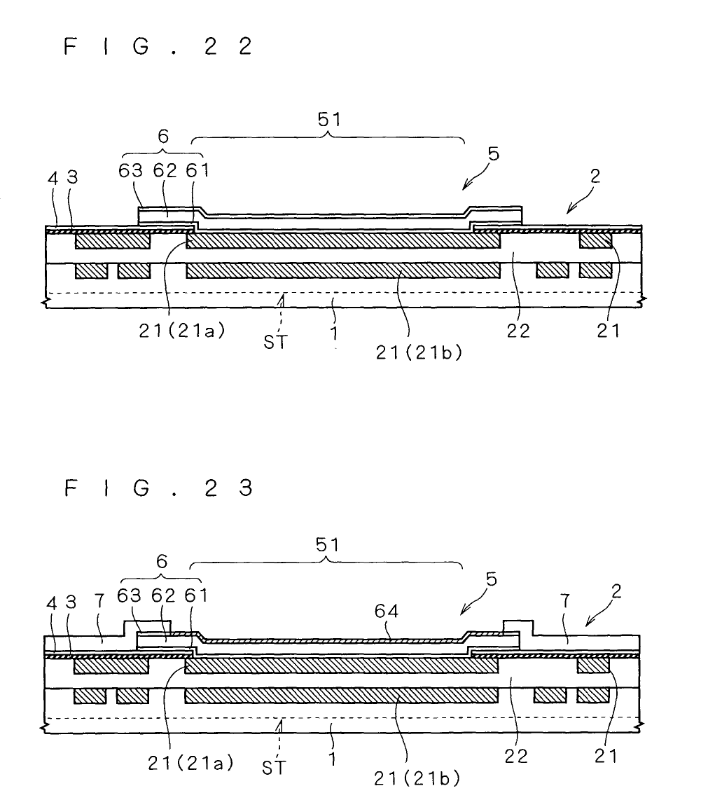

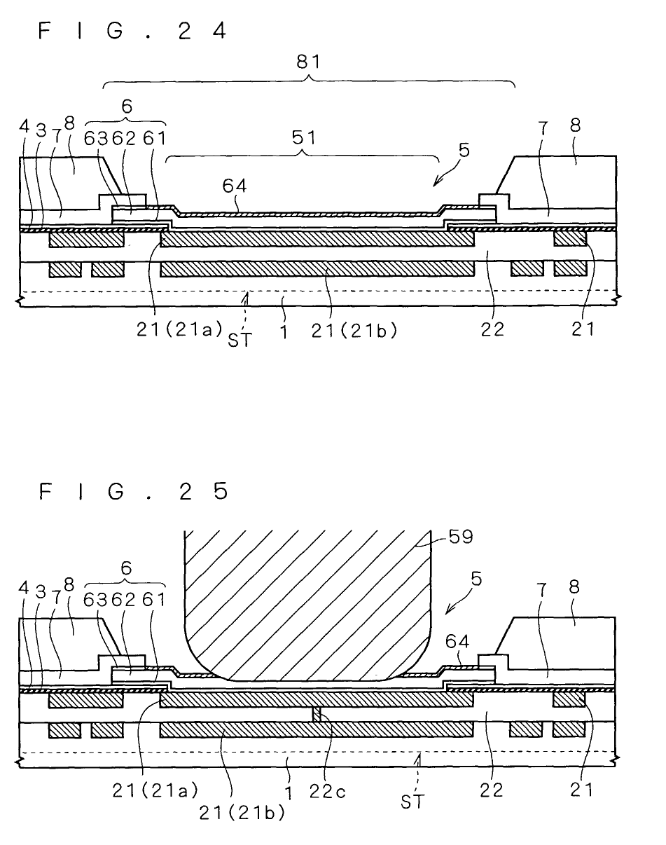

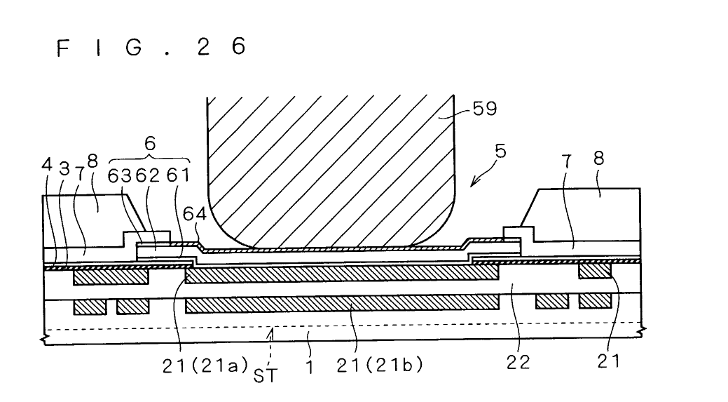

In each of the above described preferred embodiments, it is not essential to form numerous fine protrusions on the Cu wiring layer 2. As one alternative, a plurality of films 55 forming a plurality of linear bands may be provided as illustrated in FIG. 19A (the films 55 are radially arranged in an example shown in FIG. 19A). As another alternative, a plurality of films 56 forming a plurality of circular bands or rings which are concentric with each other about a portion close to a center of the pad area may be provided as shown in FIG. 19B. Also the above noted films, which are selectively formed in the pad area 5, can reduce a contact area between the surface of the pad area 5 and a probe, thereby to make it possible to easily peel off the alumina layer 64 using the probe 59. Moreover, though at least one protrusion is required in the protrusion layer PT1, it is preferable to form a plurality of protrusions which are distributed throughout the entire pad area 5.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
(a) a semiconductor substrate including a semiconductor element area;
(b) a wiring layer formed on a main surface of said semiconductor substrate;
(c) a protrusion layer selectively formed on said wiring layer in a predetermined pad area, said protrusion layer including at least one protrusion; and
(d) a conductive layer covering an uneven surface made of respective exposed surfaces of said protrusion layer and said wiring layer in said predetermined pad area, to include irregularities extending along said uneven surface.

2. The semiconductor device according to claim 1, wherein
said protrusion layer is formed of an insulative material.

3. The semiconductor device according to claim 1, wherein
said protrusion layer is formed of a conductive material.

4. The semiconductor device according to claim 1, wherein
said protrusion layer is thinner than said conductive layer.

5. The semiconductor device according to claim 1, wherein
said protrusion layer includes a plurality of protrusions.

6. The semiconductor device according to claim 5, wherein
said plurality of protrusions are arranged so as to form a grid.

7. The semiconductor device according to claim 5, wherein
each of said plurality of protrusions is substantially circular in section taken along a plane parallel to said wiring layer.

8. The semiconductor device according to claim 5, wherein
said plurality of protrusions are arranged radially from around a center of said predetermined pad area.

9. The semiconductor device according to claim 5, wherein
said plurality of protrusions are arranged so that said plurality of protrusions are concentric with each other about a center of said predetermined pad area.

10. The semiconductor device according to claim 5, wherein
each of said plurality of protrusions is conical in section taken along a plane perpendicular to said wiring layer.
